(19) United States
(12) Patent Application Publication
(10) Pub. No.: US 2005/0243882 A1
(43) Pub. Date: Nov. 3, 2005

(54) DUAL-WAVELENGTH SEMICONDUCTOR LASER

(76) Inventors: Jian-Jun He, Ottawa (CA); Michael Cada, Halifax (CA)

Correspondence Address: LIGHTIP TECHNOLOGIES, INC., 40 COLLEGE CIRCLE, OTTAWA, ON, K1K-4R8, CA

(21) Appl. No.: 10/908,058

(22) Filed: Apr. 26, 2005

Related U.S. Application Data
(60) Provisional application No. 60/566,223, filed on Apr. 29, 2004.

(51) Int. Cl. H01S 5/00

(52) U.S. Cl. 372/50.121; 372/50.1

(57) ABSTRACT

A monolithically integrated dual-wavelength laser comprises at least three coupled Fabry-Perot cavities in tandem, each separated by a vertically etched air gap of a size that is substantially equal to an odd-integer multiple of quarter-wavelength. The first two cavities are of substantially comparable lengths and are actively pumped to provide gains to the combined cavity laser, and to produce a series of double-peaked lasing modes. The other cavity has a substantially smaller length and acts as an optical filter to select one of the doublets of the combined cavity as the lasing modes. The beating between the two modes of the dual-wavelength laser at a photodetector produces a microwave carrier signal whose frequency can be tuned by adjusting the balance of the injected currents between the two active cavities.

### RELATED APPLICATIONS

This application claims benefit from U.S. Provisional Patent Application Ser. No. 60/566,223, filed on Apr. 29, 2004, entitled “Dual-wavelength laser for microwave carrier generation”.

### FIELD OF THE INVENTION

This invention relates generally to a semiconductor laser, and more particularly to an integrated dual-wavelength semiconductor laser for microwave carrier generation.

### BACKGROUND OF THE INVENTION

Broadband millimeter-wave-over-fiber transmission has received great interest recently for new generation wireless access systems and local multipoint distribution services. It allows many of the complex system functions to be done remotely rather than at numerous antenna sites. Many different techniques have been developed to generate optical signals modulated at millimeter-wave frequencies. One of the promising techniques is to use the beating of two optical frequency components separated by the required millimeter-wave frequency on a high-speed photodetector. At present, this is commonly done by combining two commercially available single-frequency laser diodes. In order to achieve good stability of the millimeter-wave frequency and low phase noise, milli-Kelvin precision laser temperature control and techniques such as optical phase-lock loop are required, which adds complexity and cost. Reducing the linewidth of the generated millimeter-wave to desired values is thus a difficult task.

It is advantageous to generate two wavelength components separated by a desired millimeter-wave frequency from a single laser. This eliminates any effect of temperature fluctuation and provides a millimeter wave with a stable frequency. It is also desirable to be able to tune the frequency of the millimeter-wave, i.e., the frequency difference of the two lasing wavelengths. Furthermore, it is desirable to be able to integrate the photodetector on the same chip and also to implement phase-locking mechanism in an integrated fashion to further improve the linewidth.

It is an object of the present invention to provide a monolithically integrated semiconductor laser that produces two wavelengths simultaneously with the possibility of integrating all above desirable features, and that has the advantages of compactness, simple fabrication process and low cost.

### SUMMARY OF THE INVENTION

In accordance with the invention, there is provided, a monolithically integrated dual-wavelength laser comprising:
a first optical cavity having two partially reflecting elements,
a second optical cavity having two partially reflecting elements, said second optical cavity being coupled with the first optical cavity through a common partially reflecting element,
a first active waveguide within the first optical cavity and a second active waveguide within the second optical cavity, each of said active waveguides being sandwiched between a pair of electrodes for injecting current to provide optical gain,
an optical filter comprising at least a passive optical cavity having two partially reflecting elements, said passive optical cavity being coupled with the second optical cavity through a common partially reflecting element,
wherein the coupled first and second optical cavities produces a series of doublets of lasing modes with substantially the same lasing threshold, and wherein the optical filter selects one of the doublets as the lasing modes.

In accordance with another embodiment of the invention, there is provided, a monolithically integrated dual-wavelength laser comprising:
a first active optical cavity having two partially reflecting elements and a first active waveguide, said first active waveguides being sandwiched between a pair of electrodes for injecting current to provide optical gain,
a second active optical cavity having two partially reflecting elements and a second active waveguide, said second active optical cavity being coupled with the first active optical cavity through a common partially reflecting element, said second active waveguides being sandwiched between a pair of electrodes for injecting current to provide optical gain,
a first optical filter comprising a first passive optical cavity having two partially reflecting elements, said first passive optical cavity being coupled with the first active optical cavity through a common partially reflecting element,
a second optical filter comprising a second passive optical cavity having two partially reflecting elements, said second passive optical cavity being coupled with the second active optical cavity through a common partially reflecting element,
wherein the coupled first and second active optical cavities produces a series of doublets of lasing modes with substantially the same lasing threshold, and wherein the first and the second optical filters select one of the doublets as the lasing modes.

### BRIEF DESCRIPTION OF THE DRAWINGS

FIG. 1 is prior art semiconductor lasers based on a Fabry-Perot cavity (a) and a DFB grating (b).

FIG. 2 is a schematic drawing of an integrated dual-wavelength laser in accordance with the present invention.

FIG. 3 is the reflectivity and transmission coefficients of the air gap as a function of the gap size at 1550 nm wavelength.

FIG. 4 is a simplified structure of two coupled Fabry-Perot cavities without the etalon filter.

FIG. 5 is the calculated below-threshold small signal gain spectra of the structure of FIG. 4 with cavity lengths L₁=L₂=428.5 μm, and for g₁=g₂=13.75 cm⁻¹ (solid line) and g₁=1.63 cm⁻¹, g₂=25.87 cm⁻¹ (dotted line).

FIG. 6 is the variation of the frequency difference as a function of the gain coefficient g₁ of the first cavity while keeping the sum of the two gain coefficients constant for the cases (a) L₁=L₂=428.5 μm, g₁+g₂=27.5 cm⁻¹; and (b) L₁=L₂=214.3 μm, g₁+g₂=55 cm⁻¹.

FIG. 7 is the reflectivity spectrum of an etalon filter of length Lₚ=20 μm terminated by a cleaved facet on one end and a 5λ/4 air gap on the other end.

FIG. 8 is the small signal gain spectrum for the case L₁=L₂=214.3 μm, and Lₚ=20 μm, which is calculated at the lasing threshold of the doublet around 1550.12 nm with equal gain coefficients g₁=g₂=14.8 cm⁻¹.

FIG. 9 is a schematic drawing of an integrated dual-wavelength laser comprising two active cavities and two etalon filters in accordance with another embodiment of the present invention.

FIG. 10 is the reflectivity spectra of two etalon filters with 9λ/4 etched trenches filled with a material (e.g. silicon nitride) of a refractive index of 2.3, for a cavity length of Lₚ₁=20 μm (solid line) and Lₚ₂=61.25 μm (dashed line).

FIG. 11 is the calculated below-threshold small signal gain spectra for the complete laser structure including two active cavities and two etalon filters.

FIG. 12 is the threshold gains of different modes when the filter is tuned to 1550.12 nm.

### DETAILED DESCRIPTION

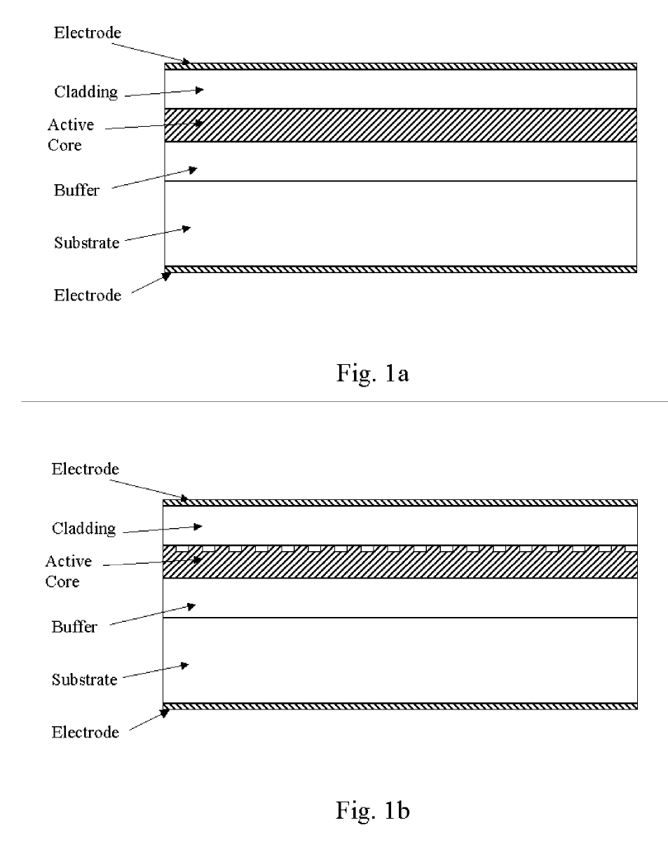

FIG. 1(a) is a schematic drawing of a prior-art semiconductor Fabry-Perot laser. The light bounces back and forth between two mirrors, which are formed by cleaving the facets of the semiconductor crystal. The waveguide region between the two mirrors is pumped electrically with current injection to provide amplification of light. Because of the periodic longitudinal mode structure of the Fabry-Perot cavity, the mode selectivity is only provided by the spectral distribution of the material gain. Due to spacial hole-burning effect, the laser is usually multimode with unstable intensity distribution between different modes.

FIG. 1(b) is a schematic drawing of another prior-art semiconductor laser based on distributed feedback (DFB) grating. Unlike a Fabry-Perot laser, a DFB laser has a grating etched into the gain region. This grating serves the purpose of stabilizing the frequency of the laser, making the laser single-mode with a precise wavelength for applications in fibre-optic transmission systems.

For microwave carrier generation, it is required that the laser emit at two wavelengths with a precise frequency difference and stable intensities. Two section DFB lasers have been proposed for such purpose, as described in a paper entitled “Tunable Millimeter-Wave Generation with Subharmonic Injection Locking in Two-Section Strongly Gain-Coupled DFB Lasers”, J. Hong and R. Hui, IEEE PHOTONICS TECHNOLOGY LETTERS, VOL. 12, NO. 5, MAY 2000. A similar design employing a dual-mode laser with two DFB sections and a phase section is reported in a paper entitled “Optical Millimeter-Wave Generation and Wireless Data Transmission Using a Dual-Mode Laser”, G. Grosskopf et al, IEEE PHOTONICS TECHNOLOGY LETTERS, VOL. 12, NO. 12, DECEMBER 2000. Because of the DFB gratings and associated phase controls, these lasers are difficult to fabricate.

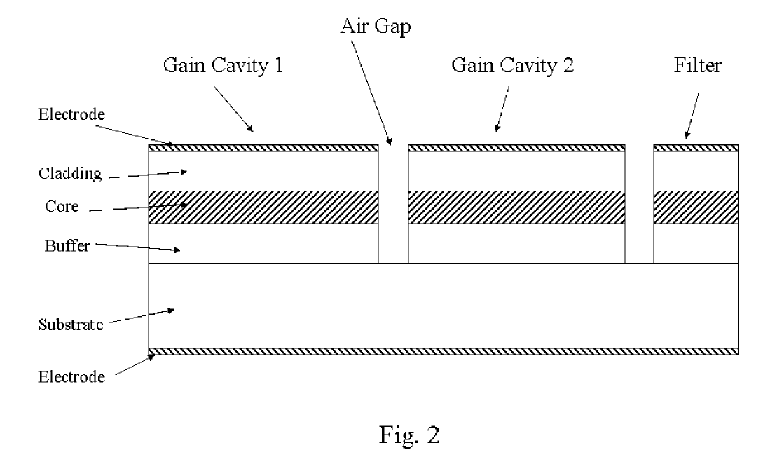

FIG. 2 illustrates a monolithic dual-wavelength laser in accordance with the present invention. It comprises three coupled Fabry-Perot cavities in tandem, each separated by a vertically etched air gap of a size that is substantially equal to an odd-integer multiple of quarter-wavelength. The first two cavities are of substantially the same lengths and are actively pumped to provide gains to the combined cavity laser, and to produce a series of double-modes. The third cavity has a substantially smaller length and acts as an etalon filter to select one of the doublets of the combined cavity as the lasing modes. The beating between the two modes at a photodetector produces a microwave carrier signal. By adjusting the balance of the injected currents between the two active cavities, the frequency difference of the double modes can be varied without affecting their relative intensities. The central wavelength of the passive filter can be slightly tuned by changing its refractive index either through carrier injection or through reverse-biased electro-optic effect. An electrical feedback signal is applied to slightly adjust the central wavelength of the filter to stabilize the relative intensities of the two lasing modes.

The waveguide structure generally consists of a buffer layer, waveguide core layer that also provides gain when electrically pumped, and upper cladding layer, deposited on a substrate. An electrode layer is deposited on the top surface. The backside of the substrate is also deposited with another metal electrode layer as a ground plane. The electrodes provide a means for injecting current to produce optical gains, and in the case of the etalon filter, also to change the refractive index of the waveguide. Preferably, the waveguide core layer comprises multiple quantum wells as in conventional laser structure, and the layers are appropriately doped. In the transverse direction, standard ridge or rib waveguides are formed to laterally confine the optical mode.

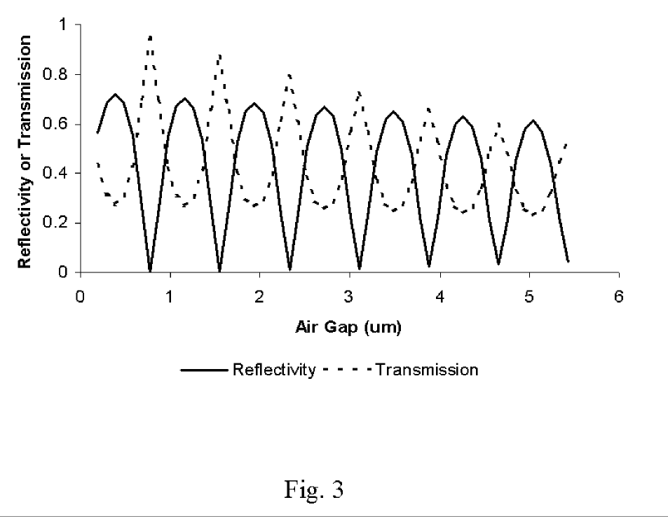

The air gaps in the structure act as high-reflectivity mirrors for the cavities. In order to achieve high reflectivity, the gap size must be substantially equal to an odd-integer multiple of the quarter-wavelength, i.e., λ/4, 3λ/4, 5λ/4, . . . etc. FIG. 3 shows the reflectivity and transmission coefficient of the air gap as a function of the gap size at 1550 nm wavelength. If the gap size is equal to an even-integer multiple of the quarter-wavelength (i.e. λ/2, λ, 3λ/2, . . . etc), the air gap forms a resonant cavity itself and its reflectivity is almost negligible. The whole device behaves essentially as a single cavity laser (formed by the two cleaved facets) rather than multiple coupled cavities.

Theoretically, the best performance is obtained with the smallest air gap, i.e., λ/4. This is because the loss at the unguided air gap increases as the gap size increases, due to beam divergence. Consequently, the peak reflectivity decreases, as can be seen in FIG. 3. On the other hand, the fabrication becomes more challenging as the gap decreases, since a λ/4 gap is only 0.3875 μm for 1550 nm wavelength. A 5λ/4 to 9λ/4 gap, corresponding to a size of 1.94 μm to 3.49 μm, can be a good compromise. The error tolerance on the gap should be in the order of ±0.1 μm for InP based material system, regardless of the gap size. This is achievable with current state of the art fabrication technologies.

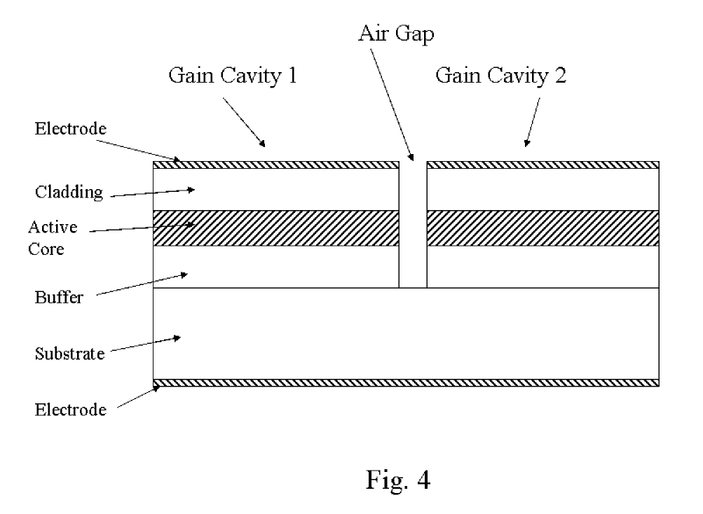

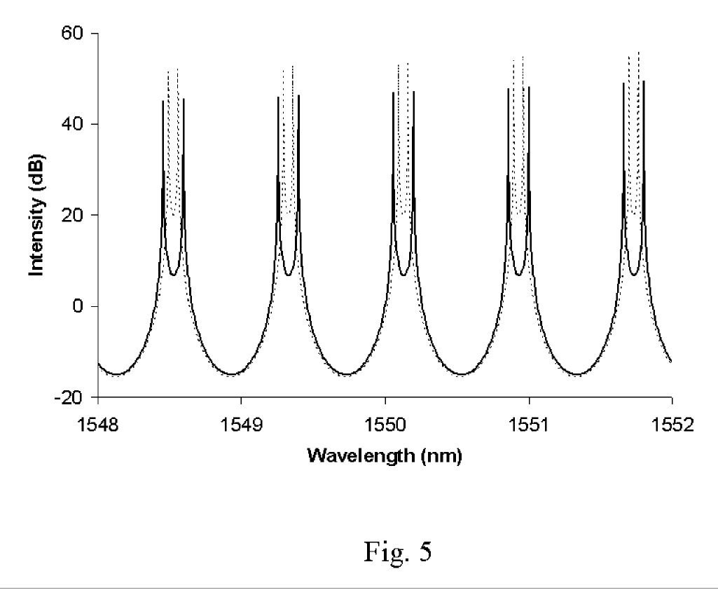

To illustrate the operating principle of the dual-wavelength laser, we first consider a simplified structure with only two coupled Fabry-Perot cavities (without the etalon filter), as shown in FIG. 4. We calculated the small-signal gain of the structure with an incident light coupled from the cleaved facet of the first gain cavity, using the transfer matrix method. In our numerical examples, we assume the effective refractive index of the waveguide is 3.5. FIG. 5 shows the calculated small signal gain spectra for the case where both cavities have the same length (L₁=L₂=428.5 μm). The solid curve is the case where the two cavity waveguides are pumped with the same gain coefficients slightly below the threshold (g₁=g₂=13.75 cm⁻¹). It features a series of doublets corresponding to the longitudinal modes of the combined cavity. The distance between the doublets is determined by the free spectral range of the cavities, which is 0.8 nm in this example. The separation between the two peaks of each doublet is 0.143 nm, corresponding to a frequency difference of 18 GHz.

If the two cavities are pumped differently, the separation between the twin peaks of a doublet is reduced. However, the intensities of the twin peaks remain identical. For example, for the dotted line in FIG. 5, which is calculated for the case g₁=1.63 cm⁻¹ and g₂=25.87 cm⁻¹, the separation between the twin peaks becomes 0.066 nm, corresponding to a frequency difference of about 8.3 GHz.

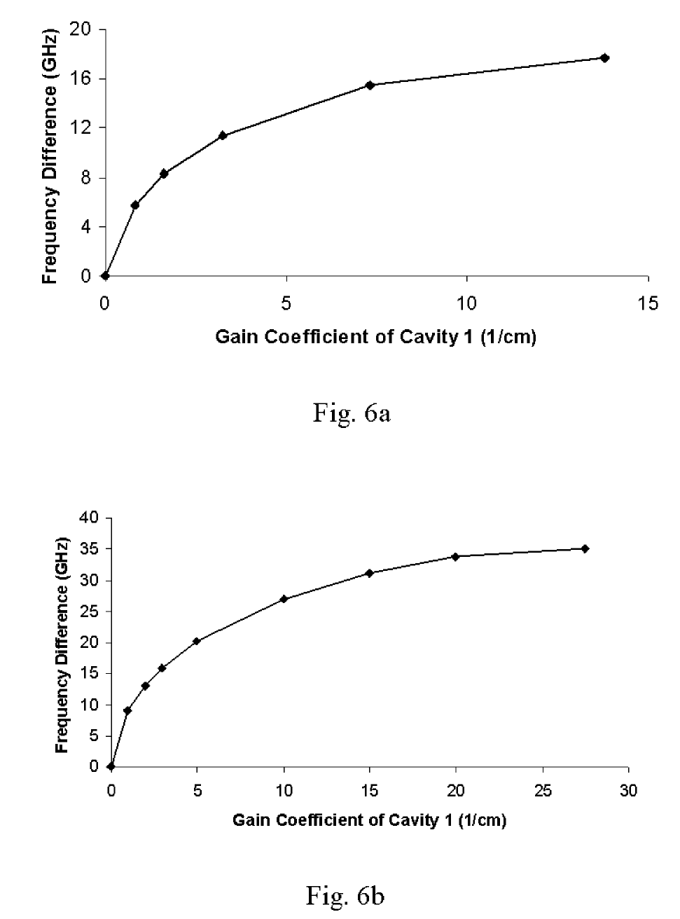

FIG. 6 (a) shows the variation of the frequency difference as a function of the gain coefficient g₁ of the first cavity, while keeping the sum of the two gain coefficients constant, i.e. g₂=27.5 cm⁻¹−g₁. Therefore, we can tune the frequency difference by adjusting the balance of the pumping levels between the two cavities, but only up to a maximum value (18 GHz in this example).

The maximum frequency difference (corresponding to equal pumping levels for the two cavities) can be increased by reducing the cavity length of the cavities. For example, for L₁=L₂=274.3 μm, the lasing threshold of the combined cavity at equal pumping becomes g₁=g₂=27.5 cm⁻¹. The solid line in FIG. 6 (b) shows the variation of the frequency difference as a function of the gain coefficient g₁ of the first cavity, while keeping the sum of the two gain coefficients constant at 55 cm⁻¹, i.e. g₂=55 cm⁻¹−g₁. The maximum frequency that can be achieved in this case becomes 35 GHz. Higher frequencies can be achieved by further reducing the cavity length.

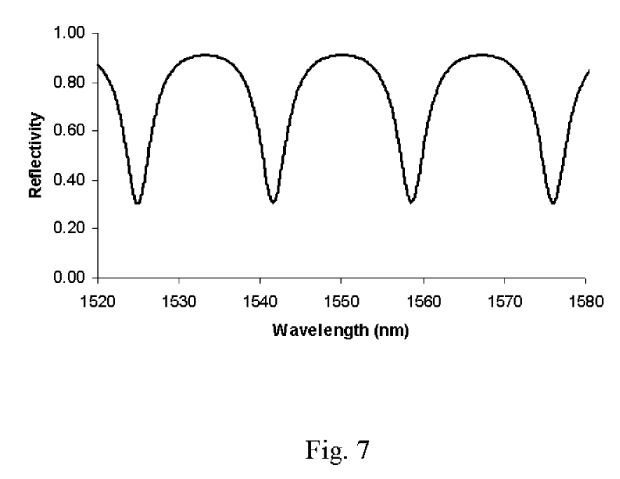

According to the present invention, an optical filter is used to select only one of the doublets to lase. The optical filter is implemented in an integrated manner using one or more passive Fabry-Perot cavities. The term “passive” here means that no gain is provided in those cavities. However, optionally, electrical means may be provided to change the refractive index to tune the wavelength of the filter. The dual-wavelength laser incorporating a single Fabry-Perot etalon as a filter is shown in FIG. 2. FIG. 7 gives the reflectivity spectrum of the etalon filter including the 5λ/4 air gap, for a cavity length Lₚ=20 μm. With the inclusion of the etalon filter, the combined-cavity modes located at the peak (˜1550.12 nm) of the filter reflectivity spectrum will have the lowest lasing threshold.

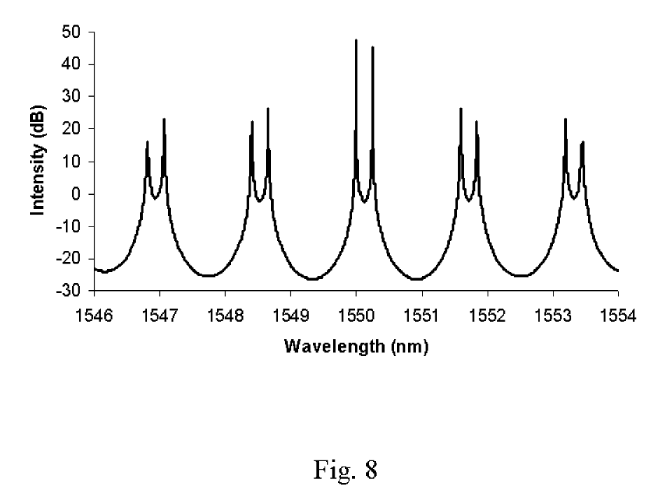

FIG. 8 shows the small signal gain spectrum of the complete laser structure for the case L₁=L₂=214.3 μm, and Lₚ=20 μm, which is calculated at the lasing threshold of the doublet around 1550.12 nm with equal gain coefficients g₁=g₂=14.8 cm⁻¹. The small signal gain of the doublet at the peak of the filter reflectivity spectrum becomes much higher than those of other modes.

The free spectral range of the filter is related to its length by Δf=c/2n_{g}Lₚ, where c is the light velocity in vacuum, n_{g} the effective group refractive index of the waveguide, and Lₚ the passive filter cavity length. In order not to have more than one doublet lasing simultaneously, Δf_{c} should be at least comparable to the spectral width of the material gain window. This requires that the filter cavity length to be small. On the other hand, a short cavity results in a broad filter function, which leads to a low mode selectivity for adjacent doublets. Obviously, a more complex filter can be designed by using multiple Fabry-Perot cavities that produce a narrow reflectivity peak and a large free spectral range.

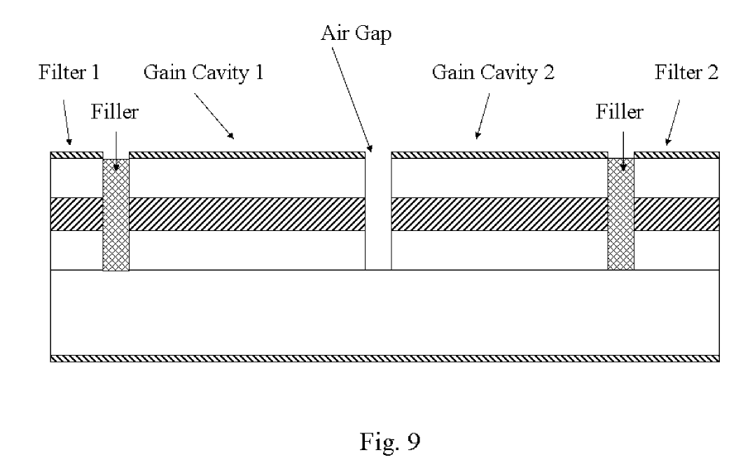

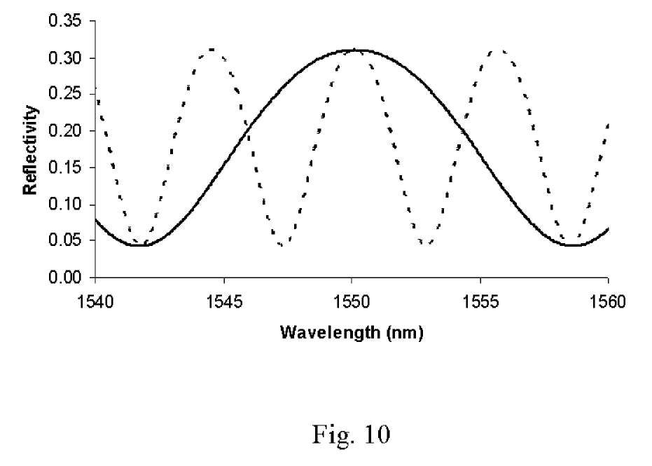

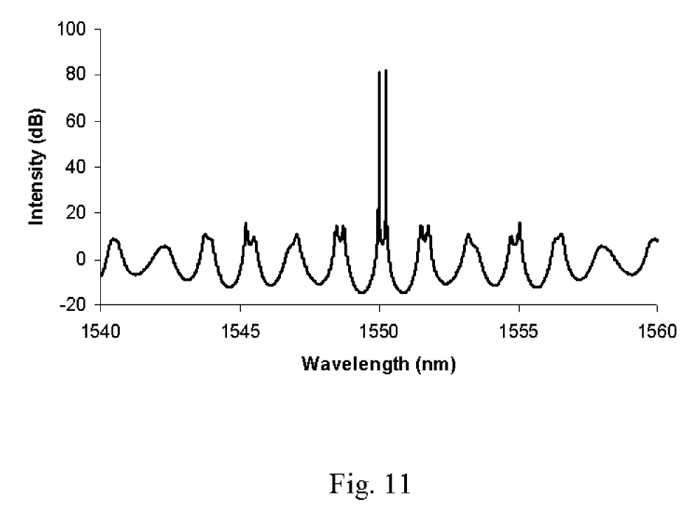

To improve the mode selectivity, it is also possible to add an etalon filter at each of the two active cavities, i.e., by replacing each of the two cleaved facets with an etalon filter, as schematically shown in FIG. 9. By combining two etalon filters of different lengths, a narrow filtering function with a large free spectral range can be achieved. In order not to affect the tuning curve of the difference frequency, the etalon filters can be designed such that they have the same peak reflectivity as a cleaved facet. This can be realized by using deep-etched trenches filled with an intermediate refractive index material or by using shallow-etched trenches. FIG. 10 shows the reflectivity spectra of two etalon filters with the 9λ/4 etched trenches filled with a material with refractive index of 2.3, for a cavity length of Lₚ₁=20 μm and Lₚ₂=61.25 μm, respectively. FIG. 11 shows the small signal gain spectra of the complete laser structure including the two etalon filters and two active cavities of lengths L₁=L₂=214.3 μm. It is calculated at the lasing threshold of the doublet around 1550.12 nm with gain coefficients g₁=g₂=27.3 cm⁻¹.

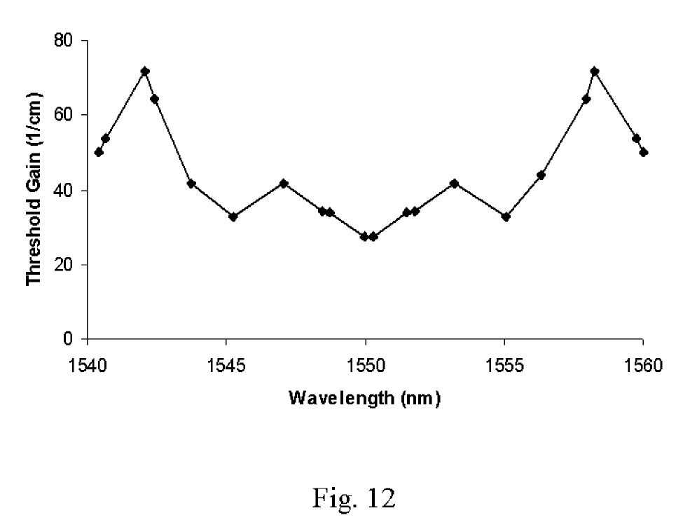

The mode selectivity of the laser can be characterized by threshold difference between the side modes and the main modes. FIG. 12 shows the lasing thresholds for different modes. The lowest threshold for side modes is about 33.9 cm⁻¹ in this example. A threshold difference as large as 24% is achieved between the side modes and the main modes. The spectral gain distribution of the active waveguide material is not considered in the above calculations, which would further increase the mode selectivity.

If the central wavelength of the optical filter is located at the middle of the selected doublet, the two lasing modes will have the same lasing threshold and output power. However, due to the existence of mode competition in the laser cavity and unstable environment conditions such as the temperature variation, the output power of the two modes may fluctuate. To stabilize the relative power of the two modes, an electrical feedback signal can be applied to the optical filters to change slightly the refractive index of the passive waveguide and consequently to shift slightly the central wavelength of the optical filters. A photodetector can be integrated on the chip to generate the beat signal of the two lasing modes that can be used as the feedback to maintain constant power of the millimeter wave carrier. An injection locking technique can also be implemented by applying a subharmonic modulation signal on at least one of the gain sections to stabilize the beating frequency and to reduce the linewidth of the generated millimeter-wave signal.

For the passive cavity, the waveguide material needs to be substantially transparent while its refractive index needs to be adjustable by an electrical means. One way to maintain transparency or low loss while producing the required refractive index change is to use passive waveguide material with a larger bandgap and to use carrier injection for the refractive index change. The integration with the active waveguide can be done by using the etch-and-regrowth technique or a post-growth bandgap engineering method such as quantum well intermixing. An alternative is to pump active laser material close to transparency.

Numerous other embodiments can be envisaged without departing from the spirit and scope of the invention. For example, the single air gap separating the cavities can be replaced by multiple air gaps. The gaps can be filled with a material of intermediate material such as silicon oxide or silicon nitride. The cleaved facets can be coated with dielectric thin-films. Etched facets or air gaps can also be used as reflectors to replace the cleaved end facets of the laser.

1. A monolithically integrated dual-wavelength laser comprising:
a first optical cavity having two partially reflecting elements,
a second optical cavity having two partially reflecting elements, said second optical cavity being coupled with the first optical cavity through a common partially reflecting element,
a first active waveguide within the first optical cavity and a second active waveguide within the second optical cavity, each of said active waveguides being sandwiched between a pair of electrodes for injecting current to provide optical gain,
an optical filter comprising at least a passive optical cavity having two partially reflecting elements, said passive optical cavity being coupled with the second optical cavity through a common partially reflecting element,
wherein the coupled first and second optical cavities produces a series of doublets of lasing modes with substantially the same lasing threshold, and wherein the optical filter selects one of the doublets as the lasing modes.

2. A monolithically integrated dual-wavelength laser as defined in claim 1, wherein the optical cavities are coupled through air gaps.

3. A monolithically integrated dual-wavelength laser as defined in claim 2, wherein the air gaps have vertically-etched sidewalls and are of a size that is substantially equal to an odd-integer multiple of quarter-wavelength.

4. A monolithically integrated dual-wavelength laser as defined in claim 1, wherein the first and the second optical cavities have substantially the same length.

5. A monolithically integrated dual-wavelength laser as defined in claim 1, wherein the balance of the currents injected into the first and the second active waveguides is adjusted to vary the frequency difference of the two lasing modes.

6. A monolithically integrated dual-wavelength laser as defined in claim 1, wherein the optical filter further comprises a substantially transparent waveguide, said waveguide being sandwiched between a pair of electrodes for providing an electrical means to vary the effective refractive index of the waveguide and consequently to tune the wavelength of the optical filter for adjusting the power balance of the two lasing modes.

7. A monolithically integrated dual-wavelength laser as defined in claim 6, wherein the electrical means is affected by a feedback signal for stabilizing the relative intensities of the two lasing modes.

8. A monolithically integrated dual-wavelength laser comprising:
a first active optical cavity having two partially reflecting elements and a first active waveguide, said first active waveguides being sandwiched between a pair of electrodes for injecting current to provide optical gain,
a second active optical cavity having two partially reflecting elements and a second active waveguide, said second active optical cavity being coupled with the first active optical cavity through a common partially reflecting element, said second active waveguides being sandwiched between a pair of electrodes for injecting current to provide optical gain,
a first optical filter comprising a first passive optical cavity having two partially reflecting elements, said first passive optical cavity being coupled with the first active optical cavity through a common partially reflecting element,
a second optical filter comprising a second passive optical cavity having two partially reflecting elements, said second passive optical cavity being coupled with the second active optical cavity through a common partially reflecting element,
wherein the coupled first and second active optical cavities produces a series of doublets of lasing modes with substantially the same lasing threshold, and wherein the first and the second optical filters select one of the doublets as the lasing modes.

9. A monolithically integrated dual-wavelength laser as defined in claim 8, wherein the optical cavities are coupled through air gaps.

10. A monolithically integrated dual-wavelength laser as defined in claim 9, wherein the air gaps have vertically-etched sidewalls and are of a size that is substantially equal to an odd-integer multiple of quarter-wavelength.

11. A monolithically integrated dual-wavelength laser as defined in claim 8, wherein the optical cavities are coupled through etched gaps filled with a material of an intermediate refractive index.

12. A monolithically integrated dual-wavelength laser as defined in claim 11, wherein the filled gaps have vertically-etched sidewalls and have an optical path length that is substantially equal to an odd-integer multiple of quarter-wavelength.

13. A monolithically integrated dual-wavelength laser as defined in claim 8, wherein the first and the second active optical cavities have substantially the same length.

14. A monolithically integrated dual-wavelength laser as defined in claim 8, wherein the balance of the currents injected into the first and the second active waveguides is adjusted to vary the frequency difference of the two lasing modes.

15. A monolithically integrated dual-wavelength laser as defined in claim 8, wherein the first and the second passive optical cavities have substantially different lengths for producing a narrow filtering function with a large free spectral range.

16. A monolithically integrated dual-wavelength laser as defined in claim 8, wherein each of the first and the second optical filters further comprises a substantially transparent waveguide, said waveguide being sandwiched between a pair of electrodes for providing an electrical means to vary the effective refractive index of the waveguide and consequently to tune the wavelength of the optical filter for adjusting the power balance of the two lasing modes.

17. A monolithically integrated dual-wavelength laser as defined in claim 16, wherein the electrical means is affected by a feedback signal for stabilizing the relative intensities of the two lasing modes.
